(19) United States
(12) Patent Application Publication
(10) Pub. No.: US 2011/0048755 A1
(43) Pub. Date: Mar. 3, 2011

(54) HOUSING FOR ELECTRONIC DEVICE AND METHOD FOR MAKING THE SAME

(75) Inventors: HSIANG-JUNG SU, Shindian (TW); WEN-TE LAI, Shindian (TW)

(73) Assignee: FIH (HONG KONG) LIMITED, Kowloon (HK)

(21) Appl. No.: 12/766,996

(22) Filed: Apr. 26, 2010

(30) Foreign Application Priority Data
Aug. 26, 2009 (CN) 200910306121.8

(51) Int. Cl. H05K 5/00; B32B 38/10; C23F 1/00; B21D 22/00

(52) U.S. Cl. 174/50; 156/153; 216/58; 72/352

(57) ABSTRACT

A housing for electronic device, comprising: a metal substrate, the substrate having a bonding surface, a peripheral edge, and a ridge protruding from the peripheral edge and surrounding the bonding surface; a soft layer soft to the touch, the soft layer having an edge; and an adhesive layer located between the bonding surface of the substrate and the soft layer, thereby bonding the soft layer to the substrate, the ridge of the substrate blocking the edge of the soft layer. A method for making the present housing is also provided.

### BACKGROUND

1. Technical Field

The present disclosure generally relates to housings for electronic devices, especially to a housing soft to the touch, and a method for making the housing.

2. Description of Related Art

Housings for electronic devices made of metal may have good strength but are hard to the touch and are decorated by environmentally unfriendly means such as electroplating and/or painting.

Therefore, there is room for improvement within the art.

### BRIEF DESCRIPTION OF THE DRAWINGS

Many aspects of the housing for electronic device and method for making the housing can be better understood with reference to the following drawings. The components in the drawings are not necessarily to scale, the emphasis instead being placed upon clearly illustrating the principles of the present housing and the method for making the same.

FIG. 1 is an isometric, exploded view of an exemplary embodiment of the present housing.

FIG. 2 is a schematic integral view of the housing shown in FIG. 1.

FIG. 3 is a schematic cross-section view of the housing shown in FIG. 2 taken along line III-III.

### DETAILED DESCRIPTION

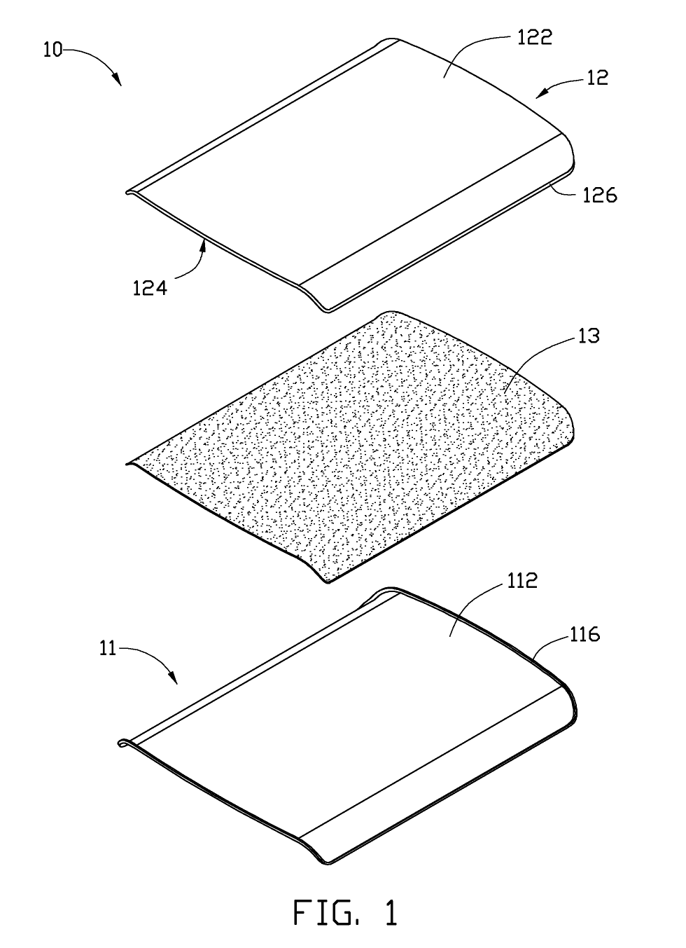

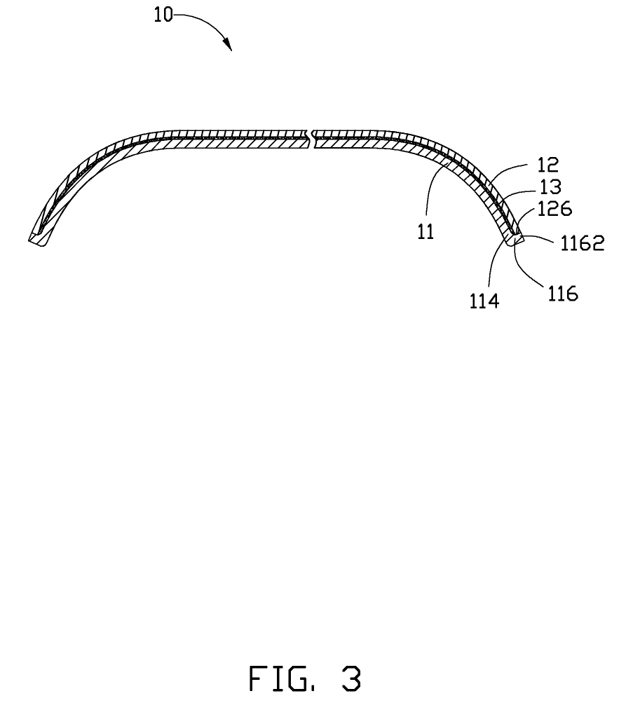

FIG. 1 and FIG. 3 show an exemplary housing 10 for an electronic device such as a mobile phone. The housing 10 includes a substrate 11, and a soft layer 12 bonded to the substrate 11 by an adhesive layer 13.

The substrate 11 can be made of metal, such as stainless steel, magnesium alloy, aluminum alloy, titanium alloy etc. The substrate 11 has a bonding surface 112, a peripheral edge 114, and a ridge 116 protruding from the peripheral edge 114 and surrounding the bonding surface 112. The bonding surface 112 may be roughened (e.g., by etching or grinding) facilitating a good bonding of the soft layer 12 to the substrate 11. The ridge 116 has an end surface 1162 (best shown in FIG. 3) extends from the peripheral edge 114. The length of the ridge 116 from peripheral edged 114 to the end surface 1162 is about equal to the combined thickness of the soft layer 12 and the adhesive layer 13.

The soft layer 12 is comprised of a material that is soft to the touch. Exemplary material suitable for the soft layer 12 can be leather or fabric such as cloth. The soft layer 12 has an outer surface 122, an inner surface 124, and an edge 126. The inner surface 124 of the soft layer 12 acts as a bonding surface. The inner surface 124 may be roughened, and form, for example, a plurality of tiny pores or projections. For some soft materials, the pores and projections of the inner surface 124 may be a natural property of the material. For other soft materials, the pores and projections may be formed by, for example, weaving or sandblasting the inner surface 124.

The adhesive layer 13 is comprised of an adhesive, such as polyurethane, alkyd resin, polyvinyl alcohol, or polyacrylate type adhesive. In this embodiment, the polyurethane adhesive is used.

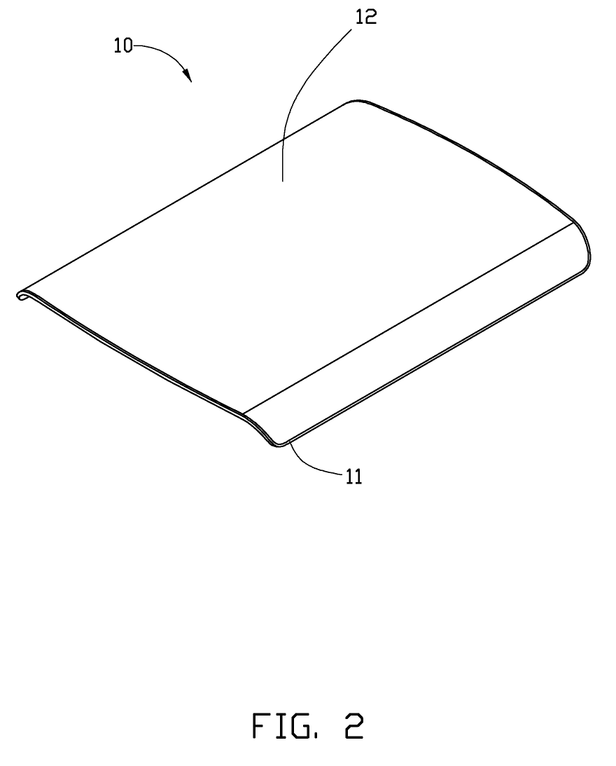

Referring to FIG. 2 and FIG. 3, the adhesive layer 13 is located between the bonding surface 112 of the substrate 11 and the inner surface 124 of the soft layer 12, thereby bonding the soft layer 12 to the substrate 11. The ridge 116 blocks the edge 126 of the soft layer 12, thereby protecting the soft layer 12 from peeling off. The ridge 116 has its end surface 1162 coplanar with the outer surface 122 of the soft layer 12.

An exemplary method for making the housing 10 may include the following steps.

The substrate 11 is manufactured. The substrate 11 includes the bonding surface 112 and the ridge 116. During this step, a preformed substrate is formed without the ridge 116 by stamping. Then, the ridge 116 is formed by, for example forging.

The bonding surface 112 of the substrate 11 is roughened by chemical process or mechanical process. The chemical process can be a process of etching using chemicals. The mechanical process may be one of grinding using sandpaper, electrospark roughening, threading, and knurling. In this embodiment, the bonding surface 112 is chemically etched. For example, when the substrate 11 is made of stainless steel, the substrate 11 can be roughened in a hydrochloric acid solution containing trivalent iron.

The adhesive layer 13 is formed on the bonding surface 112 by, e.g., spot gluing.

A soft layer 12 is provided. The soft layer 12 has the outer surface 122, the inner surface 124 and the edge 126. The inner surface 124 is rough or coarse by inclusion of tiny pores or projections.

The soft layer 12 is placed on the bonding surface 112 having the adhesive layer 13 formed thereon. The edge 126 of the soft layer 12 resists the ridge 116, resulting the edge 126 blocked by the ridge 116.

Once the adhesive layer 13 is solidified, suitable pressure can be applied on the soft layer 12 to strengthen the bonding of the substrate 11 and the soft layer 12.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing for electronic device, comprising:
a metal substrate, the substrate having a bonding surface, a peripheral edge, and a ridge protruding from the peripheral edge and surrounding the bonding surface;
a soft layer soft to the touch, the soft layer having an edge; and
an adhesive layer located between the bonding surface of the substrate and the soft layer, thereby bonding the soft layer to the substrate, the ridge of the substrate blocking the edge of the soft layer.

2. The housing as claimed in claim 1, wherein the bonding surface is rough.

3. The housing as claimed in claim 1, wherein the soft layer has an outer surface and an inner surface, the inner surface having a plurality of tiny pores or projections formed thereon, the inner surface bonding the adhesive layer.

4. The housing as claimed in claim 3, wherein the ridge has an end surface away from the peripheral edge, the end surface being coplanar with the outer surface of the soft layer.

5. The housing as claimed in claim 1, wherein the soft layer is made of leather or fabric.

6. The housing as claimed in claim 4, wherein the adhesive layer is comprised of one of the polyurethane, alkyd resin, polyvinyl alcohol, and polyacrylate type adhesive.

7. The housing as claimed in claim 1, wherein the substrate is made of a metal selected from the group consisting of stainless steel, magnesium alloy, aluminum alloy, and titanium alloy.

8. A method for making a housing, comprising:
providing a metal substrate, the substrate having an bonding surface, a peripheral edge, and a ridge protruding from the peripheral edge and surrounding the bonding surface;
roughening the bonding surface;
forming an adhesive layer on the roughened bonding surface;
providing a soft layer, the soft layer having a soft tactility and an edge;
placing the soft layer on the bonding surface having the adhesive layer formed thereon; and
solidifying the adhesive layer, thereby the adhesive layer bonds the soft layer and the substrate.

9. The method as claimed in claim 8, wherein the method further comprising applying a proper pressure on the soft layer to strengthen the bonding of the substrate and the soft layer.

10. The method as claimed in claim 8, wherein the step of manufacturing the substrate comprising forming a preformed substrate free of the ridge by stamping, and forming the ridge by forging.

11. The method as claimed in claim 8, wherein the bonding surface is roughened by chemical etching or mechanical process.

12. The method as claimed in claim 11, wherein the mechanical process is selected from one of the processes of grinding using sandpaper, electrospark roughening, threading, and knurling.

13. The method as claimed in claim 8, wherein the adhesive is formed by spot gluing.

14. The method as claimed in claim 8, wherein the soft layer has an outer surface and an inner surface, the inner surface having a plurality of tiny pores or projections formed thereon, the inner surface bonding the adhesive layer.

15. The method as claimed in claim 14, wherein the ridge has an end surface extending from the peripheral edge, the end surface being coplanar with the outer surface of the soft layer.

16. The method as claimed in claim 8, wherein the soft layer is made of leather or fabric.

17. The method as claimed in claim 8, wherein the substrate is made of a metal selected from the group consisting of stainless steel, magnesium alloy, aluminum alloy, and titanium alloy.
